(19) United States
(12) Patent Application Publication
(10) Pub. No.: US 2026/0009849 A1
(43) Pub. Date: Jan. 8, 2026

(54) SYSTEM AND METHOD FOR DESIGNING CLOCK MANAGEMENT UNIT USING A NO-CODE APPROACH

(71) Applicant: ITDA SEMICONDUCTOR CO., LTD., Hwaseong-si (KR)

(72) Inventors: Ingyu KIM, Hwaseong-si (KR); Hoyeon JEON, Seongnam-si (KR); Ahchan KIM, Hwaseong-si (KR)

(73) Assignee: ITDA SEMICONDUCTOR CO., LTD., Hwaseong-si (KR)

(21) Appl. No.: 19/255,523

(22) Filed: Jun. 30, 2025

(30) Foreign Application Priority Data
Jul. 2, 2024 (KR) 10-2024-0086592
Feb. 26, 2025 (KR) 10-2025-0024857

(51) Int. Cl. G01R 31/3185; G01R 31/317

(52) U.S. Cl. CPC G01R 31/318547; G01R 31/31727

(57) ABSTRACT

A system and method for designing a clock management unit using a no-code approach capable of testing a clock component that configures a clock management unit and generating a test clock along a functional clock generation path. The at least one instruction includes instructions for: generating a clock instance including a clock source block, a clock control signal block, and a test multiplexer block based on clock component information; generating a test mode controller instance including a test mode TDR block and a test control TDR block corresponding to the test multiplexer block; setting a connection between the test multiplexer block and the test mode controller instance; and generating hardware code based on connection information and the hardware code logic of the clock instance and the test mode controller instance.

### STATEMENT REGARDING GOVERNMENT SPONSORED RESEARCH OR DEVELOPMENT

This invention was made with support from the Ministry of SMEs and Startups through a grant funded by the Korea Technology and Information Promotion Agency for SMEs (TIPA), under Project Unique Number 1425182152 and Project Number RS-2023-00302523, within the Startup Growth Technology Development (R&D) program. The project titled “Low-Code Based Low-Power Semiconductor Solution” was executed by ITDA Semiconductor Co., Ltd., with the research period spanning from Jul. 1, 2023, to Jun. 30, 2026. However, no rights in the invention are held by the government of the Republic of Korea.

### CROSS-REFERENCE TO RELATED APPLICATION

This application claims the benefit of and priority to Korean Patent Application Nos. 10-2024-0086592, filed on Jul. 2, 2024, and 10-2025-0024857, filed on Feb. 26, 2025, the entire disclosures of which are incorporated herein by reference in their entirety.

### TECHNICAL FIELD

The present disclosure relates to a system and method for designing a clock management unit of a system-on-chip, and more particularly, to a system and method for designing the clock management unit using a no-code approach, which enables testing of clock components included in the clock management unit and generation of a test clock along a functional clock generation path.

### BACKGROUND

A system-on-chip (SoC) refers to a semiconductor integrated circuit or a technology for integrating various functional blocks, such as a central processing unit (CPU), memory, interface, digital signal processing circuit, and analog signal processing circuit, into a single chip to implement a computer system or other electronic system. The SoC has evolved into a more complex system that includes various functional blocks, such as a processor, multimedia, graphics, interface, and security.

The SoC may operate in a test mode to detect defects during the design and manufacturing processes and to verify proper operation, and may operate in a functional mode when the test is passed and the system functions normally.

In general, power and clock design are important in a system-on-chip (SoC). The power and clock design process of the SoC may include: a power/clock diagram drawing stage; a Verilog coding and scripting stage; a primary documentation stage; a unified power format (UPF)/standard design constraint (SDC) file generation stage; an implementation layout design stage; a secondary documentation stage; a design-for-testability (DFT) controller insertion stage; a hardware system analysis stage; and a software optimization stage.

The power/clock diagram drawing stage visually represents the power and clock structures by creating a block diagram that shows the power domains and clock tree. In this stage, only the clock elements and their link relationships are illustrated in diagram form. The Verilog coding and scripting stage performs the register transfer level (RTL) design of the hardware by writing Verilog code and scripts used to define and implement the functions of the SoC. That is, the developer manually generates RTL code based on the results of the power/clock diagram drawing stage.

The primary documentation stage is a stage in which the design intent and structure are documented at the beginning of a project, and various types of documents such as requirements specifications, architecture designs, and power/clock diagrams are prepared for multiple stakeholders, including a verification team and a software development team.

The UPF/SDC file generation stage is a stage of generating Unified Power Format (UPF) and Standard Design Constraint (SDC) files for controlling power management and timing constraints, and generating input data required for hardware synthesis.

The implementation layout design stage is a stage of designing and performing placement of the actual SoC chip layout at the gate level. The secondary documentation stage is a stage of updating and supplementing various documents to reflect changes in the design and implementation. The DFT controller insertion stage is a stage of designing and integrating DFT controllers and logic circuits into the SoC for testing and debugging. The hardware system analysis stage is a stage of verifying and analyzing the operation of the hardware through simulation to ensure the accuracy and efficiency of the design. The software optimization stage is a stage of profiling and optimizing the software code executed on the SoC to optimize the software performance.

In the power/clock diagram drawing stage, a path of a functional clock operating in a functional mode is designed, and in the DFT controller insertion stage, a path of a test clock operating in a test mode is designed. Conventionally, the functional clock design stage and the test clock design stage have been performed separately. Accordingly, the clock management unit is designed to provide the functional clock to the IP block through a functional clock path in the functional mode, and to provide the test clock to the IP block through a test clock path different from the functional clock path in the test mode.

The clock management unit designed in this manner does not drive a clock component of the clock management unit in a test mode of the system-on-chip (SoC), and thus it is not possible to test whether the clock component operates normally.

In addition, since the functional clock path and the test clock path are different, a frequency of a test clock provided to an IP block in a test mode may differ from a frequency of a functional clock provided to the IP block in a functional mode, which may result in a difference between a voltage margin in the test mode and a voltage margin in the functional mode, thereby causing an increase in a defect rate and a decrease in chip yield during mass production.

### SUMMARY

An aspect of the present disclosure is directed to providing a system and method for designing a clock management unit using a no-code approach, which enables a test clock generated through the same path as a functional clock path in a test mode to be provided to an IP block and enables testing of each clock component configuring the clock management unit.

An embodiment of the present disclosure may be implemented in various ways, including a device (system), a method, a computer program stored in a computer-readable medium, or a computer-readable medium having a computer program stored therein.

A system for designing a clock management unit using a no-code approach according to an embodiment of the present disclosure includes: a memory configured to store at least one instruction; a clock component storage storing clock component information that configures the clock management unit; a hardware code logic storage storing hardware code logic for generating the designed clock management unit as hardware code; and at least one processor configured to execute the at least one instruction stored in the memory. The at least one instruction includes instructions for: generating a clock instance including a clock source block, a clock control signal block, and a test multiplexer block based on the clock component information; generating a test mode controller instance including a test mode TDR block and a test control TDR block corresponding to the test multiplexer block; setting a connection between the test multiplexer block and the test mode controller instance; and generating the hardware code based on connection information and the hardware code logic of the clock instance and the test mode controller instance.

Preferably, the at least one instruction includes instructions for generating a scan controller instance corresponding to the clock control signal block, setting a connection between the clock control signal block and the scan controller instance, and generating hardware code based on the scan controller instance, the connection information and the hardware code logic.

Preferably, the test mode controller instance is implemented based on a built-in IEEE1687 standard.

Preferably, the test mode TDR block is configured to activate or deactivate a test mode, and the test control TDR block is configured to generate a test clock control signal in the test mode.

More preferably, the test control TDR block is composed of as many flip-flop blocks as the number of control bits in the clock source block.

Preferably, the test mode TDR block and the test control TDR block are each set via an internal joint test action group (IJTAG) interface.

Preferably, the clock component is any one of a PLL controller component, a clock divider component, a clock multiplexer component, and a clock gate component.

A method for designing a clock management unit using a no-code approach according to an embodiment of the present disclosure is performed by at least one processor in a computer system including a clock component storage storing clock component information that configures the clock management unit and a hardware code logic storage storing hardware code logic for generating the designed clock management unit as hardware code. The method for designing the clock management unit using the no-code approach includes: generating a clock instance including a clock source block, a clock control signal block, and a test multiplexer block based on the clock component information; generating a test mode controller instance including a test mode TDR block and a test control TDR block corresponding to the test multiplexer block; setting a connection between the test multiplexer block and the test mode controller instance; and generating hardware code based on connection information and the hardware code logic of the clock instance and the test mode controller instance.

Preferably, the method further includes: generating a scan controller instance corresponding to the clock control signal block: setting a connection between the clock control signal block and the scan controller instance: and generating hardware code based on the scan controller instance, the connection information and the hardware code logic.

Preferably, the test mode controller instance is implemented based on a built-in IEEE1687 standard.

Preferably, the test mode TDR block is configured to activate or deactivate a test mode, and the test control TDR block is configured to generate a test clock control signal in the test mode.

More preferably, the test control TDR block is composed of as many flip-flop blocks as the number of control bits in the clock source block.

Preferably, the test mode TDR block and the test control TDR block are each set via an internal joint test action group (IJTAG) interface.

Preferably, the clock component is any one of a PLL controller component, a clock divider component, a clock multiplexer component, and a clock gate component.

A computer program stored in a computer-readable medium is provided for executing the aforementioned method according to an embodiment of the present disclosure on a computer.

### Advantageous Effects

An embodiment of the present disclosure provides the following benefits.

According to an embodiment of the present disclosure, when the path of the functional clock operating in a functional mode is designed in a power/clock diagram drawing stage, the test clock path operating in a test mode can be automatically designed at the same time.

According to an embodiment of the present disclosure, since a separate DFT controller insertion stage can be omitted, the resources required for designing a clock management unit are reduced, and the efficiency of the design work can be effectively improved.

According to an embodiment of the present disclosure, an operator can design a test mode control system that controls the clock management unit in the test mode using a no-code approach without any coding knowledge or clock process knowledge.

According to an embodiment of the present disclosure, since a test clock of the same path as a functional clock path is generated, the clock management unit capable of testing whether clock components configuring the functional clock path operate normally in the test mode can be designed.

An embodiment of the present disclosure is configured to separate the clock components into a low-speed domain and a high-speed domain, wherein the low-speed domain can be designed to be tested using a reference clock of a scan chain for logic testing of a system-on-chip device, and the high-speed domain can be designed to be tested with a test clock having the same frequency as the functional clock, using the same circuit as the functional clock path.

The clock management unit designed according to an embodiment of the present disclosure provides the test clock to an IP block when the system-on-chip device is driven in the test mode, thereby smoothly performing an IP block test.

Since the clock management unit designed according to an embodiment of the present disclosure is configured to generate the test clock through the same path as the functional clock path, the frequency of the test clock is the same as the frequency of the functional clock used in the functional mode, so that the voltage margin in the test mode and the voltage margin in the functional mode are identical, thereby reducing the defect rate in mass production and improving the chip yield.

The benefits of the present disclosure are not limited to those mentioned above, and other benefits not mentioned herein will be clearly understood by those having ordinary skill in the technical field to which the present disclosure pertains (hereinafter, “those skilled in the art”) from the following description.

### BRIEF DESCRIPTION OF THE DRAWINGS

Embodiments of the present disclosure will be described with reference to the accompanying drawings described below, where similar reference numerals indicate similar elements, but embodiments are not limited thereto, in which:

FIG. 1 is a block diagram illustrating a typical system-on-chip (SoC);

FIG. 2 is a detailed configuration block diagram illustrating a clock management unit 200 included in the SoC of FIG. 1;

FIG. 3 is a partial detailed diagram illustrating the clock management unit of FIG. 2;

FIG. 4 is a partial detailed diagram illustrating the clock management unit designed based on an embodiment of the present disclosure;

FIG. 5 is a configuration diagram illustrating a system for designing a clock management unit using a no-code approach according to an embodiment of the present disclosure;

FIG. 6 is a diagram illustrating an example of a display screen of a system for designing a clock management unit using a no-code approach according to an embodiment of the present disclosure;

FIG. 7 is an operation flow diagram illustrating a method for designing a clock management unit using a no-code approach according to an embodiment of the present disclosure; and

FIG. 8 illustrates an exemplary computing device for performing the method and/or embodiments described above.

### DETAILED DESCRIPTION

Hereinafter, specific details for the practice of the present disclosure will be described in detail with reference to the accompanying drawings. However, in the following description, detailed descriptions of well-known functions or configurations will be omitted when it may make the subject matter of the present disclosure rather unclear.

In the accompanying drawings, the same or corresponding components are assigned the same reference numerals. Further, in the following description of the embodiments, duplicate descriptions of the same or corresponding components may be omitted. However, even if descriptions of components are omitted, it is not intended that such components are not included in any embodiment.

The advantages and features of the embodiments of the present disclosure and methods of achieving the same will be apparent from the embodiments described below in connection with the accompanying drawings. However, the present disclosure is not limited to the disclosed embodiments disclosed below, and may be implemented in various different forms, and the present embodiments are merely provided to fully disclose the scope of embodiments to those skilled in the art to which the present disclosure pertains.

The terms used herein will be briefly described prior to describing the disclosed embodiments in detail. The terms used herein have been selected as general terms which are widely used at present in consideration of the functions of the present disclosure, and this may be altered according to the intent of a person skilled in the art, conventional practice, or introduction of new technology. Further, in a specific case, a term is arbitrarily selected by the applicant, and the meaning of the term will be described in detail in a corresponding description of the embodiments. Accordingly, the terms used in the present disclosure should be defined based on the meaning of the terms and the overall content of the present disclosure rather than a simple name of each of the terms.

As used herein, the singular forms are intended to include the plural forms as well, unless the context clearly indicates the singular forms. Further, the plural forms are intended to include the singular forms as well, unless the context clearly indicates the plural forms. Further, throughout the description, when a portion is stated as including a component, it intends to mean that the portion may additionally include another component, rather than excluding the same, unless specified to the contrary.

In this present disclosure, the terms “comprising,” “having,” or the like are used to specify that features, steps, operations, elements and/or components exists, and they do not preclude the addition of one or more other features, steps, operations, elements, components, and/or combinations thereof.

In the present disclosure, when a particular component is referred to as being “coupled to,” “combined with,” “connected to,” “related to,” or as “responding to” any other component, the particular component may be directly coupled to, combined with, connected to, and/or related to, or may directly respond to the other component; however, the present disclosure is not limited to the relationship. For example, there may be one or more intermediate components between a particular component and another component. In addition, in the present disclosure, “and/or” may include one or more of the listed items or a combination of at least a portion of one or more of the listed items.

In the present disclosure, the terms such as “first” and “second” are used to distinguish a particular component from the other components, and thus the component should not be limited by those terms. For example, a “first” component may be used to indicate a component in a form similar to or the same as a “second” component.

In an embodiment of the present disclosure, the term “clock component” may be clock tools that may be utilized in designing a clock management unit. The clock component may include a PLL controller component, a clock divider component, a clock multiplexer component, and a clock gate component. In an embodiment of the present disclosure, the clock component may be displayed as an icon in a clock component window.

In an embodiment of the present disclosure, the term “clock instance” may be a clock component added to a design window by the manipulation of a user. In other words, the clock instance may be a clock component included in the design of the clock management unit. When the user drags and drops a clock component icon from the clock component window into the design window area, a corresponding clock instance may be generated. Upon generation, a basic register and, optionally, an extension register associated with the clock instance may also be automatically created. The field values configuring the basic and extension registers may be preset or may be modified by user input.

The clock management unit may include a plurality of clock instances for each type of clock component. A clock instance generated based on the PLL controller component is referred to as a PLL controller instance, a clock instance generated based on the clock divider component is referred to as a clock divider instance, a clock instance generated based on the clock multiplexer component is referred to as a clock multiplexer instance, and a clock instance generated based on the clock gate component is referred to as a clock gate instance.

In an embodiment of the present disclosure, a clock element may be a hardware-coded module that is generated based on a completed design of a clock instance, and may be configured to constitute the clock management unit.

Accordingly, the clock component may serve as a material for designing the clock management unit; the clock instance may be a node included in the design of the clock management unit; and the clock element may be a hardware-coded module based on a completed clock instance, which is operable within the clock management unit.

In an embodiment of the present disclosure, the clock instance is a node included in the design of the clock management unit and may include a clock source block, a clock control signal block, and a test multiplexer block. The clock source block, the clock control signal block, and the test multiplexer block are each implemented as hardware code and may operate as a clock source, a clock control signal, and a test multiplexer.

In an embodiment of the present disclosure, the test mode controller instance is a node included in the design of the clock management unit, and may include a test mode TDR block and a test control TDR block. The test mode controller instance, the test mode TDR block, and the test control TDR block are each implemented as hardware code and may operate as a test mode controller, a test mode TDR, and a test control TDR.

In an embodiment of the present disclosure, the scan controller instance is a node included in the design of the clock management unit, and may be implemented as hardware code and operate as a scan controller.

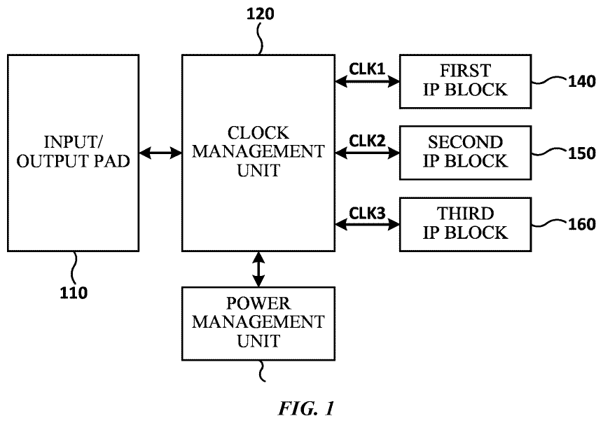

FIG. 1 is a block diagram illustrating a typical system-on-chip (SoC).

The SoC may include an input/output pad 110, a clock management unit (CMU) 120, a power management unit (PMU) 130, and one or more intellectual property (IP) blocks 140, 150, 160. When the SoC operates in a functional mode, the clock management unit 120 may generate a functional clock to be provided to each of the first to third IP blocks 140, 150, 160. For example, the clock management unit 120 may generate the first to third functional clocks (CLK1, CLK2, CLK3).

Each of the first to third IP blocks 140, 150, 160 is connected to a system bus and may communicate with each other through the system bus. Each of the first to third IP blocks 140, 150, 160 may include a processor, a graphic processor, a memory controller, an input and output interface block.

The clock management unit 120 may provide a first functional clock (CLK1) to the first IP block 140 when the first IP block 140 operates, provide a second functional clock (CLK2) to the second IP block 150 when the second IP block 150 operates, and provide a third functional clock (CLK3) to the third IP block 160 when the third IP block 160 operates. The power management unit 130 controls power supplied to the SoC. For example, when the SoC device enters a standby mode, the power management unit 130 may cut off the power supply provided to the SoC to reduce the power consumption of the SoC.

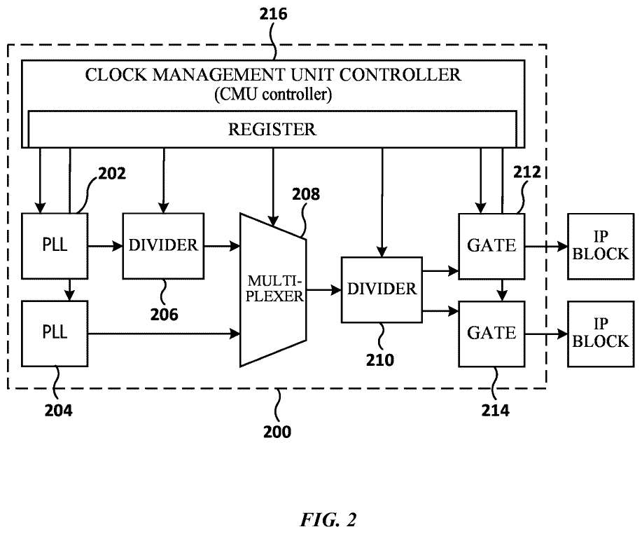

FIG. 2 is a detailed configuration block diagram illustrating a clock management unit 200 included in the SoC of FIG. 1. The clock management unit 200 of FIG. 2 may be executed in a functional mode in which the SoC operates normally. The clock management unit 200 may be the clock management unit 120 of FIG. 1.

Referring to FIG. 2, the clock management unit 200 includes a plurality of clock elements 202, 204, 206, 208, 210, 212, 214 and a clock management unit controller (CMU controller) 216. The plurality of clock elements 202, 204, 206, 208, 210, 212, 214 may generate a functional clock to be provided to an IP block. The frequencies of the functional clocks provided to each IP block may all be different. The clock management unit controller 216 controls the clock elements 202, 204, 206, 208, 210, 212, 214 to generate a functional clock having a frequency required by each IP block.

The clock elements may include a phase locked loop (PLL) controller 202, 204, a clock divider 206, 210, a clock multiplexer 208, and a clock gate 212, 214. Each clock element may include a clock source that processes a clock, and a clock control circuit that controls the clock source (CS). The CS may include, for example, a multiplexing circuit, a divider circuit, and a gate circuit.

The PLL controllers 202 and 204 do not include an internal clock source, and may control a PLL disposed outside the clock management unit 200.

The clock dividers 206, 210 each include a divider circuit as the CS, and the clock control circuit (CC) of the clock dividers 206, 210 each controls the divider circuit. The divider circuit divides an input clock and outputs the divided clock, and the clock control circuit (CC) may control the division ratio of the divider circuit.

The clock multiplexer 208 includes a multiplexing circuit as the CS, and the clock control circuit (CC) of the clock multiplexer 208 controls the multiplexing circuit. The multiplexing circuit selectively outputs one of a plurality of input clocks. The clock control circuit (CC) may control which input clock the multiplexing circuit selects and outputs.

The clock gates 212, 214 each include a gate circuit as the CS, and the clock control circuit (CC) of the clock gates 212, 214 controls the gate circuits, respectively. The gate circuit activates the clock only when the IP block needs to operate so that a functional clock is provided thereto, and otherwise blocks the clock to suppress unnecessary power consumption. The clock control circuit (CC) may control the gate circuit to activate or stop the functional clock.

The clock management unit controller 216 includes a register in which information necessary for controlling and configuring the operation of the clock management unit 200 is recorded as register transfer level (RTL) code. The register may be written with RTL code describing the operation of the clock control circuit of each clock element, and the RTL code may be implemented as actual clock management unit hardware using a hardware design tool.

The clock management unit of FIG. 2 operates in a functional mode in which the SoC operates normally, and provides a functional clock to the IP block.

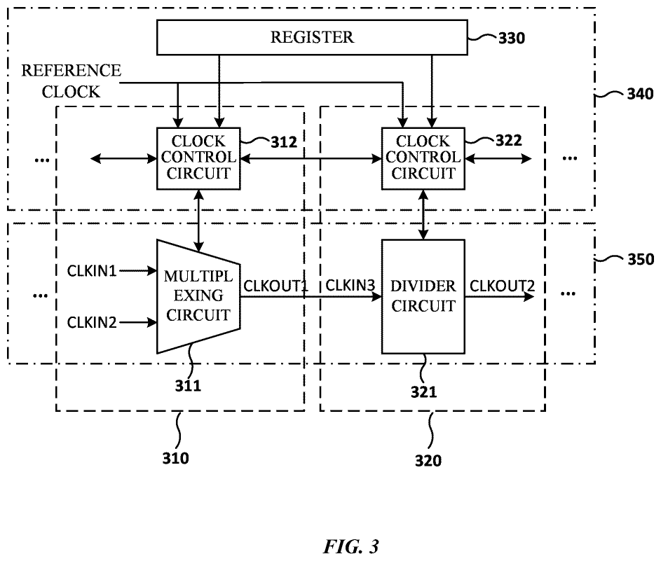

FIG. 3 is a partial detailed diagram illustrating the clock management unit of FIG. 2.

The clock management unit may include a plurality of clock elements 310 and 320. The clock elements may include a PLL controller, a clock multiplexer, a clock divider, and a clock gate. FIG. 3 illustrates an example in which a clock multiplexer 310 and a clock divider 320 are connected. Additional clock elements may be connected to a front end of the clock multiplexer 310 and a rear end of the clock divider 320. Each clock element may include a clock source that processes a clock and a clock control circuit that controls the clock source, and the clock source may include a multiplexing circuit, a divider circuit, and a gate circuit.

For example, the clock multiplexer 310 may include a multiplexing circuit 311 that processes a clock and a clock control circuit 312 that controls the multiplexing circuit 311, and the clock divider 320 may include a divider circuit 321 that processes a clock and a clock control circuit 322 that controls the divider circuit 321.

The multiplexing circuit 311 receives two or more input clocks (CLKIN1, CLKIN2) from two or more clock elements at a front end, receives a mux selection signal from the clock control circuit 312, selects one of the two or more input clocks (CLKIN1, CLKIN2) as an output clock (CLKOUT1), and provides the output clock to a clock element at a rear end. The clock control circuit 312 receives mux selection information from a register 330 and outputs the mux selection signal to the multiplexing circuit 311.

The divider circuit 321 receives, as an input clock (CLKIN3), the output clock of a clock element at its front end, receives a clock dividing ratio from the clock control circuit 322, and provides an output clock (CLKOUT2) obtained by dividing the input clock (CLKIN3) by the dividing ratio to a clock element at its rear end. The clock control circuit 322 receives the dividing ratio information from the register 330 and provides the dividing ratio to the divider circuit 321.

The clock control circuits 312 and 322 of the clock elements are usually driven by a reference clock of several tens of MHz. Meanwhile, the clock sources 311 and 321 of the clock elements process high-speed clocks ranging from several hundreds of MHz to several GHz.

The clock elements of the clock management unit may be separated into a low-speed domain 340 configured of the clock control circuits 312, 322 and a high-speed domain 350 configured of the clock sources 311, 321.

When testing the components of the low-speed domain 340 and the high-speed domain 350 of the clock management unit, since the operating clock frequency of the low-speed domain 340 and the operating clock frequency of the high-speed domain 350 are different, it is necessary to separate the test of the low-speed domain 340 and the test of the high-speed domain 350 and to design the system so that different test methods are executed for each.

Meanwhile, in the manufacturing process of the system-on-chip, it is necessary to test whether the IP block operates normally, and in a test mode, a test clock must be provided to the IP block.

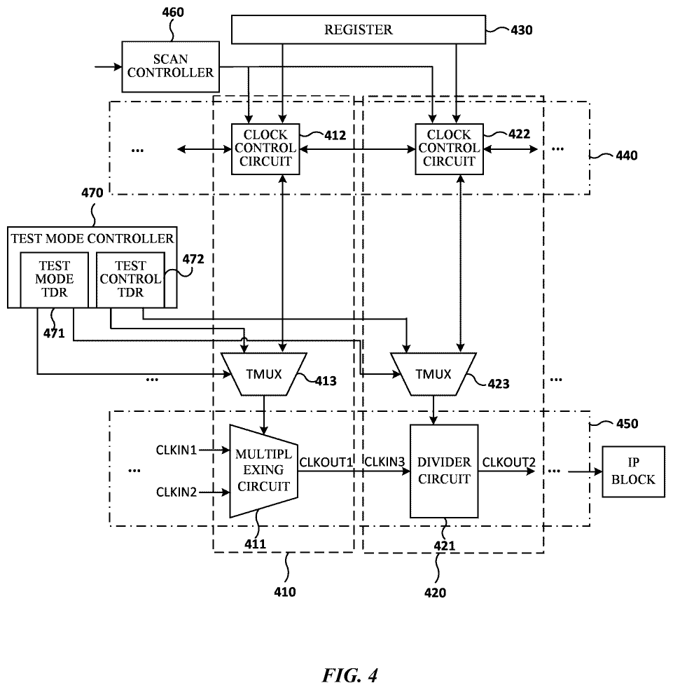

FIG. 4 is a partial detailed diagram illustrating the clock management unit designed based on an embodiment of the present disclosure.

The clock management unit of an embodiment of the present disclosure may include a plurality of clock elements 410, 420. The clock element may include a PLL controller, a clock multiplexer, a clock divider, and a clock gate. FIG. 4 illustrates an example in which the clock multiplexer 410 and the clock divider 420 are connected. The clock element is configured to include a clock source for processing a clock, a clock control circuit for outputting a functional clock control signal, and a test multiplexer (Test MUX) for outputting a functional clock control signal to the clock source under the control of a register 430 in a functional mode and a test clock control signal to the clock source in a test mode. The clock control circuit of the clock element configures a low-speed domain 440, and the clock source of the clock element configures a high-speed domain 450.

The clock multiplexer 410 includes a multiplexing circuit 411 for processing a clock, a clock control circuit 412 for outputting a functional clock control signal to the multiplexing circuit 411 under the control of the register 430 in a functional mode, and a test multiplexer 413 for receiving a functional clock control signal and a test clock control signal and selectively outputting the same to the multiplexing circuit 411. The clock divider 420 includes a divider circuit 421 for processing a clock, a clock control circuit 422 for outputting a functional clock control signal to the divider circuit 421 under the control of the register 430 in a functional mode, and a test multiplexer 423 for receiving the functional clock control signal and the test clock control signal and selectively outputting the same to the divider circuit 421. Each clock element 410, 420 includes the test multiplexer 413, 423, which is respectively matched one-to-one with the clock source 411, 421.

In addition, the clock management unit includes a scan controller 460 for controlling a reference clock supplied to the clock control circuit 412, 422 configuring a low-speed domain 440 in a test mode, and a test mode controller 470 for outputting a test clock control signal to the test multiplexer 413, 423 in a test mode.

The test multiplexer 413, 423 transmits a functional clock control signal input from the clock control circuit 412, 422 in a functional mode to the clock source 411, 421. When the SoC operates in a test mode, each test multiplexer 413, 423 transmits a test clock control signal input from the test mode controller 470 to each clock source 411, 421.

The test mode controller 470 may include a test mode test data register (TDR) 471 that activates or deactivates the test multiplexers 413, 423 in the test mode, and a test control test data register (TDR) 472 that provides a clock control signal to the test multiplexers 413, 423 activated in the test mode. The test multiplexers 413, 423 each operate in a functional mode when the test mode is deactivated and transmit the clock control signal input from the clock control circuit 412, 422 to the clock sources 411, 421. The test multiplexers 413, 423 each operate in a test mode when the test mode is activated and transmit the test clock control signal input from the test control TDR 472 of the test mode controller 470 to the clock sources 411, 421.

The test mode controller 470 may be a controller based on a built-in IEEE1687 standard. The test mode controller 470 may configure the test mode TDR 471 and the test control TDR 472 via an internal joint test action group (IJTAG) interface. The test mode TDR 471 and the test control TDR 472 may each be implemented as a flip-flop-based shift register structure.

The test mode TDR 471 may be configured with one flip-flop, and the output data of the test mode TDR 471 may be transmitted to the test multiplexers 413, 423 so that the test multiplexers 413, 423 may activate/deactivate the test mode.

The test control TDR 472 may be configured with a flip-flop chain as many as the number of bits of the test clock control signal provided to the clock source 411, 421. For example, when the number of input clocks of the multiplexing circuit 411 is 2, the multiplexing circuit 411 may output a 1-bit test clock control signal, and may output a 4-bit test clock control signal depending on the division ratio of the divider circuit 421. In this connection, the test control TDR 472 may be configured with one flip-flop for outputting the test clock control signal to the multiplexing circuit 411 and four flip-flops for outputting the test clock control signal to the divider circuit 421 in the form of a shift register chain.

The functional clock and test clock generated in the clock management unit may be transmitted to the IP block.

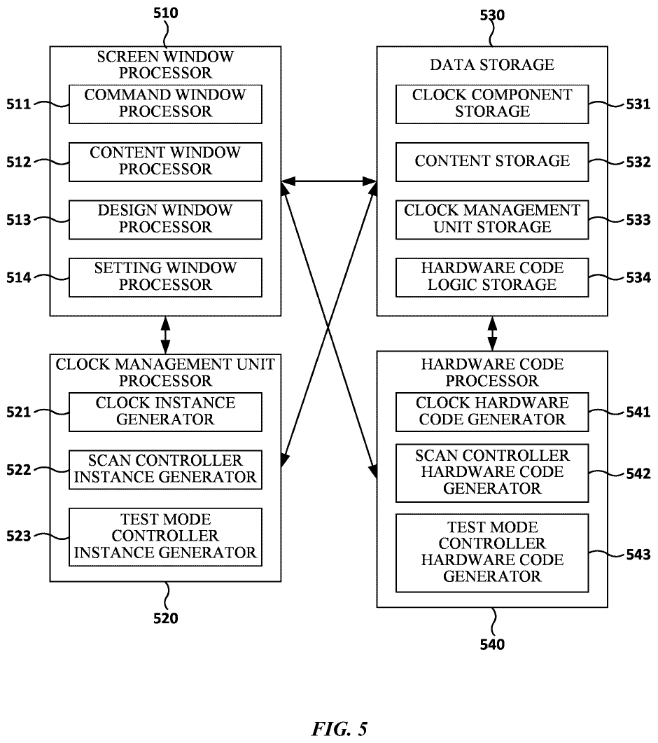

FIG. 5 is a configuration diagram illustrating a system for designing a clock management unit using a no-code approach according to an embodiment of the present disclosure. The system for designing the clock management unit using the no-code approach according to an embodiment of the present disclosure may be implemented as a computer system.

The system for designing the clock management unit using the no-code approach according to an embodiment of the present disclosure may include: a screen window processor 510 that detects a user input and outputs a processing result of the user input on a display screen; a clock management unit processor 520 that designs a clock management unit by generating at least one clock instance based on clock component information, generating a scan controller instance, setting a connection between the clock instance and the scan controller instance, generating a test mode controller instance, and setting a connection between the clock instance and the test mode controller instance; a data storage 530 that stores hardware code logic for generating hardware code based on clock component information, designed clock management unit information, and designed clock management unit; and a hardware code processor 540 that generates hardware code corresponding to the designed clock management unit using the hardware code logic.

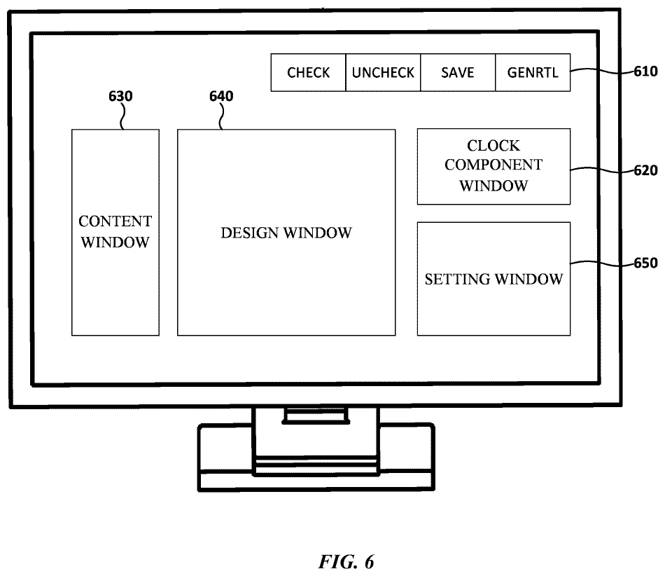

FIG. 6 is a diagram illustrating an example of a display screen of a system for designing a clock management unit using a no-code approach according to an embodiment of the present disclosure.

The display screen of the system for designing the clock management unit using the no-code approach according to an embodiment of the present disclosure may include: a command window 610 in which a user command is input; a clock component window 620 in which clock component icons are displayed; a content window 630 in which an environment for adding, deleting, and changing a list of clock management units under design is provided and a list of clock instances configuring each clock management unit under design and functional information of each clock instance are hierarchically displayed; a design window 640 in which a clock diagram of the clock management unit under design is displayed and an environment for adding, deleting, and changing a clock instance configuring the clock management unit under design are provided; and a setting window 650 in which a functional setting environment for a clock instance selected in the design window 640 is provided.

The command window 610 may include a check button for receiving a check command for errors in the clock diagram of the clock management unit under design and the setting values of clock instances that configure the clock management unit under design, an uncheck button for receiving a command to deactivate the check result, a save button for receiving a save command for the clock diagram displayed in the design window 640, and a GENRTL button for receiving a hardware code generation command for the clock diagram displayed in the design window 640.

The clock component window 620 may display icons of a clock component list that may be utilized in the design of the clock management unit. The clock components include a PLL controller component, a clock divider component, a clock multiplexer component, and a clock gate component. Each clock component internally includes a clock source block, a clock control circuit block, and a test multiplexer block. The clock source block is a design block that operates as a clock source of FIG. 4 when implemented as a clock element, the clock control circuit block is a design block that operates as a clock control circuit of FIG. 4 when implemented as a clock element, and the test multiplexer block is a design block that operates as a test multiplexer of FIG. 4 when implemented as a clock element.

The content window 630 displays a list of clock management units under design and provides an environment for adding, deleting, and modifying the clock management units under design. A list of clock instances configuring each clock management unit under design may be displayed as a sub-list under the corresponding clock management unit list. The design window 640 displays a clock diagram of the clock management unit under design and provides an environment for adding, deleting, and modifying clock instances configuring the clock management unit under design. When a user drags and drops any clock component from the clock component window 620 into the design window 640, a clock instance corresponding to the clock component may be generated in the clock management unit under design.

The setting window 650 provides an environment for setting auto clock gating (ACG) of the clock management unit under design, and provides a functional setting environment for the clock instance selected in the design window 640.

### Screen Window Processor 510

The screen window processor 510 may include: a command window processor 511 configured to display buttons for receiving user commands in the command window 610 and to detect inputs of the respective buttons such that operations corresponding to the input buttons are performed; a content window processor 512 configured to hierarchically display a list of clock management units under design, a list of clock instances included in each clock management unit under design, and register information in the content window 630, and to detect user input in the content window 630 such that operations corresponding to the user input are performed; a design window processor 513 configured to display a clock diagram of a clock management unit under design selected by a user in the design window 640 and to detect user input in the design window 640 such that operations corresponding to the user input are performed; and a setting window processor 514 configured to display ACG (Auto Clock Gating) setting information of a clock management unit under design selected by a user and setting information of a clock instance selected by the user in the setting window 650, and to detect user input in the setting window 650 such that operations corresponding to the user input are performed.

The command window processor 511, when the CHECK button is selected, checks for errors in the clock diagram of the clock management unit under design and the setting values of the clock instances configuring the clock management unit under design, so that the portion where the error occurred is displayed. When the UNCHECK button is selected, the error portion displayed in the clock diagram of the clock management unit under design is restored to its original state and displayed. When the SAVE button is selected, the work content of the clock management unit under design displayed in the design window 640 is stored in the data storage 530. When the GENRTL button is selected, hardware code is generated for the clock diagram of the clock management unit under design displayed in the design window 640.

The content window processor 512 provides an environment for adding, deleting, and changing the list of clock management units under design and the list of clock instances included in each clock management unit under design. The content window processor 512 may hierarchically display, under each clock management unit under design, the list of clock instances and register information of each clock instance. A user may add, delete, or change the name of the clock management unit under design in the content window 630, and in response to the user input, the list of clock management units under design may be added, deleted, or changed in the clock management unit storage 533. When the user changes the name of the clock management unit under design, the content window processor 512 may change not only the name of the corresponding clock management unit under design, but also the names of the clock instances and register names under the corresponding clock management unit under design in bulk.

The design window processor 513 causes a clock diagram of the clock management unit under design to be displayed in the design window 640 and provides an environment for adding, deleting, and changing clock instances that configure the clock management unit under design. When a user performs an operation of adding an arbitrary clock component from the clock component window 620 to the design window 640, the design window processor 513 detects the operation and causes a clock instance addition operation to be performed.

The setting window processor 514 causes the auto clock gating (ACG) setting information of the clock management unit under design to be displayed, and detects user input in the setting window 650 to cause an operation corresponding to the user input to be performed.

### Data Storage 530

The data storage 530 includes: a clock component storage 531 that stores clock component information; a content storage 532 that stores a list of clock instances included in a clock management unit under design and a register list corresponding to each clock instance; a clock management unit storage 533 that stores functional information of individual clock instances included in the clock management unit under design, scan controller instance information included in the clock management unit under design, and test mode controller instance information; and a hardware code logic storage 534 that stores hardware code logic for generating hardware code based on clock management unit information under design.

The clock components stored in the clock component storage 531 may include a PLL controller component, a clock divider component, a clock multiplexer component, and a clock gate component. Each clock component includes a clock source block, a clock control circuit block, and a test multiplexer block. When a clock instance corresponding to a clock component is generated, each clock instance includes the clock source block, the clock control circuit block, and the test multiplexer block. The clock instance may be implemented as a hardware code and may be operated as a clock element of FIG. 4, and the clock source block, the clock control circuit block, and the test multiplexer block may be implemented as hardware code and may be operated as the clock source, the clock control circuit, and the test multiplexer of FIG. 4, respectively.

The content storage 532 stores the ACG setting information of the clock management unit under design, a list of clock instances included in the clock management unit under design, and a register list corresponding to the clock instance.

The clock management unit storage 533 stores clock instance information for each clock instance included in the clock management unit under design, scan controller instance information included in the clock management unit under design, connection information between the clock control circuit block of the clock instance and the scan controller instance, test mode controller instance information included in the clock management unit under design, and connection information between the test multiplexer block of the clock instance and the test mode controller instance

The hardware code logic storage 534 stores hardware code logic for generating hardware code based on the designed clock management unit information, the ACG setting information of the clock management unit, the clock instance information, and the register information. When the clock instance is generated as a hardware code, it may be manufactured as a clock element, and thus, the clock control circuit block, clock source block, and test multiplexer block of each clock instance may be implemented as the clock control circuit, clock source, and test multiplexer of the clock element of FIG. 4. In addition, the scan controller instance and the test mode controller instance are implemented as the scan controller and the test mode controller of FIG. 4, respectively, and the clock control circuit and the scan controller may be connected, and the test multiplexer and the test mode controller may be connected.

### Clock Management Unit Processor 520

The clock management unit processor 520 includes: a clock instance generator 521 that generates a new clock instance including a clock source block, a clock control circuit block, and a test multiplexer block based on clock component information; a scan controller instance generator 522 that generates a scan controller instance that is connected to the clock control circuit block and configured to control a reference clock supplied to the clock control circuit block in a test mode; and a test mode controller instance generator 523 that generates a test mode controller instance that is connected to the test multiplexer block and configured to output a test clock control signal to the test multiplexer block in a test mode. The scan controller instance and the test mode controller instance are each implemented as hardware codes and may operate as the scan controller and the test mode controller of FIG. 4.

The clock instance generator 521 may be executed to generate a new clock instance when a user adds any clock component of the clock component window 620 to the design window 640. The name of the new clock instance may include the name of the clock management unit under design including the new clock instance and the clock component type information of the new clock instance. The clock instance may internally include a clock source block, a clock control circuit block, and a test multiplexer block.

The scan controller instance generator 522 may automatically operate when a clock instance is generated without a user input to generate a scan controller instance and set a connection between the scan controller instance and the clock control circuit block. The scan controller instance and the clock control circuit block may be each converted into hardware code and implemented as the scan controller 460 and the clock control circuit 412, 422 of FIG. 4.

The test mode controller instance generator 523 may automatically operate to generate a test mode controller instance when a clock instance is generated without a user input. The test mode controller instance may include a test mode TDR block and a test control TDR block. The test mode TDR block is configured to determine whether to activate the test mode of the test multiplexer block, and the test control TDR block is configured to provide a test clock control signal to the test multiplexer block. The test mode controller instance generator 523 may generate a test control TDR block configured as a flip-flop chain having a number of bits equal to that of the test clock control signal for the test multiplexer to be controlled. The test mode TDR block and the test control TDR block may be implemented as hardware code to operate as the test mode TDR and the test control TDR of FIG. 4.

The test mode controller instance is a controller based on a built-in IEEE1687 standard, and the test mode TDR block and the test control TDR block may be designed to be set through the IJTAG (Internal Joint Test Action Group) interface.

### Hardware Code Processor 540

The hardware code processor 540 may include: a clock hardware code generator 541 that generates a hardware code corresponding to a functional module of a clock element based on the designed clock instance information; a scan controller hardware code generator 542 that generates a hardware code corresponding to a scan controller based on the scan controller instance information; and a test mode controller hardware code generator 543 that generates a hardware code corresponding to a test mode controller based on the test mode controller instance information.

The hardware code processor 540 may be executed when the GENRTL button of the command window 610 is selected. A user may select and execute the GENRTL button while the clock diagram of the clock management unit under design is displayed in the design window 640, and may also execute the check button before executing the GENRTL button to verify in advance whether there is an error in the clock diagram.

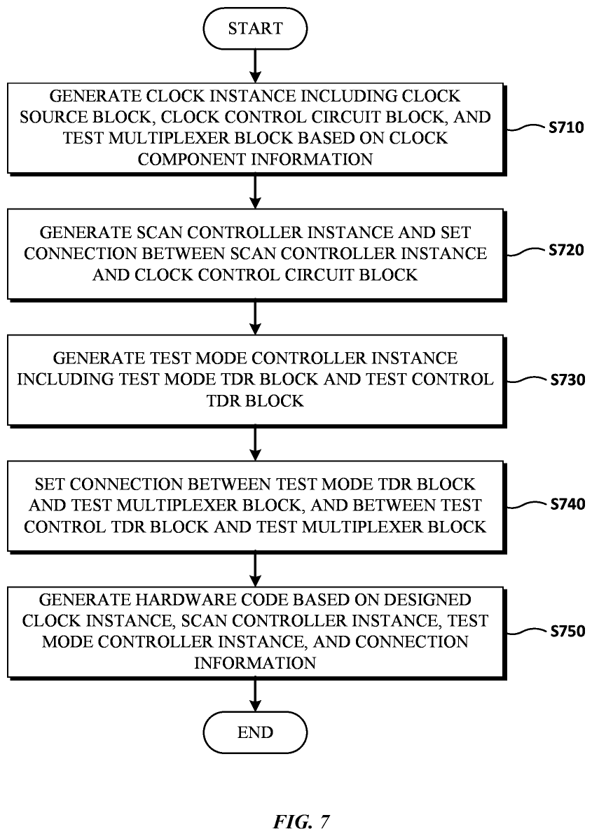

FIG. 7 is an operation flow diagram illustrating a method for designing a clock management unit using a no-code approach according to an embodiment of the present disclosure. The method for designing the clock management unit using the no-code approach according to an embodiment of the present disclosure may be executed by a processor of a computer system.

The computer system includes a clock component storage storing clock component information including a clock source block, a clock control circuit block, and a test multiplexer block, and a hardware code logic storage storing hardware code logic for generating the designed clock management unit as hardware code.

The processor generates a new clock instance including a clock source block, a clock control signal block, and a test multiplexer block based on the clock component information (S710). The processor sets a connection between the clock source block and the test multiplexer block, and sets a connection between the test multiplexer block and the clock control signal block.

The processor generates a scan controller instance for controlling a reference clock in a test mode, and sets a connection between the scan controller instance and the clock control circuit block (S720).

The processor generates a test mode controller instance for generating a test clock control signal in a test mode (S730). The test mode controller instance includes a test mode TDR block and a test control TDR block. The test control TDR block may be configured of flip-flop blocks as many as the number of control bits of the clock source block.

The processor sets connections between the test mode TDR block and the test multiplexer block, and between the test control TDR block and the test multiplexer block (S740).

The processor generates a hardware code of a clock management unit designed based on the clock instance, the scan controller instance, the test mode controller instance, the connection setting information, and the hardware code logic (S750).

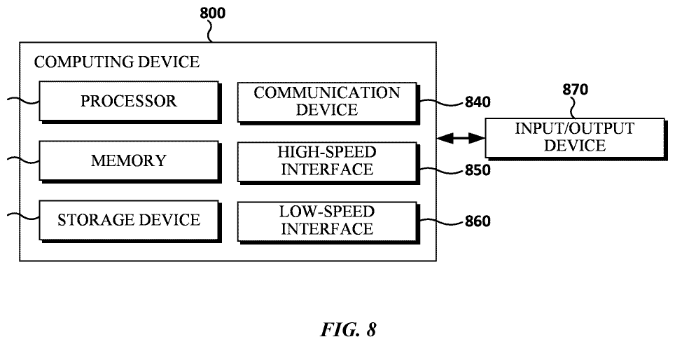

FIG. 8 illustrates an exemplary computing device 800 for performing the method and/or embodiments described above. According to an embodiment, the computing device 800 may be implemented using hardware and/or software configured to interact with a user. Herein, the computing device 800 may include a laptop computer, a desktop computer, a workstation, a personal digital assistant, a server, a blade server, and a mainframe computer, which is not limited thereto. The components of the computing device 800 and connection relationships and functions thereof are intended to be illustrative and not intended to limit the implementations of the present disclosure described and/or claimed herein.

The computing device 800 includes a processor 810, a memory 820, a storage device 830, a communication device 840, a high-speed interface 850 connected to the memory 820 and a high-speed expansion port, and a low-speed interface 860 connected to a low-speed bus and the storage device. Each of the components 810, 820, 830, 840, 850, and 860 may be interconnected using various buses, and may be mounted on the same main board or mounted and connected in other appropriate ways. The processor 810 may be configured to process instructions of a computer program by performing basic arithmetic, logic, and input/output operations. For example, the processor 810 may process instructions stored in the memory 820 or the storage device 830 and/or instructions executed within the computing device 800, and may display graphic information on an external input/output device 870, such as a display device, connected to the high-speed interface 850.

The communication device 840 may provide a configuration or function that allows the input/output device 870 and the computing device 800 to communicate with each other through a network, and may also provide a configuration or function that supports the input/output device 870 and/or the computing device 800 in communicating with another external device. For example, a request or data generated by the processor of an external device according to arbitrary program code may be transmitted to the computing device 800 through a network under the control of the communication device 840. Conversely, a control signal or command generated under the control of the processor 810 of the computing device 800 may be transmitted to another external device through the communication device 840 and the network.

FIG. 8 illustrates that the computing device 800 includes one processor 810 and one memory 820, but is not limited thereto, and the computing device 800 may be implemented using a plurality of memories, a plurality of processors, and/or a plurality of buses. In addition, although FIG. 8 describes the presence of a single computing device 800, the present disclosure is not limited thereto, and a plurality of computing devices may interact with each other and perform operations required to execute the above-described method.

The memory 820 may store information in the computing device 800. According to an embodiment, the memory 820 may be configured with a volatile memory unit or a plurality of memory units. Additionally or alternatively, the memory 820 may be configured with a non-volatile memory unit or a plurality of memory units. The memory 820 may also be implemented using another type of computer-readable medium, such as a magnetic disk or an optical disk. Further, an operating system and at least one program code and/or instructions may be stored in the memory 820.

The storage device 830 may be one or more mass storage devices for storing data for the computing device 800. For example, the storage device 830 may be or may be configured to include a computer-readable medium such as a hard disk; a magnetic disk such as a portable disk; an optical disc; a semiconductor memory device such as an erasable programmable read-only memory (EPROM), an electrically erasable PROM (EEPROM), or a flash memory device; and a CD-ROM or DVD-ROM disc. In addition, a computer program may be physically implemented on such a computer-readable medium.

The high-speed interface 850 and the low-speed interface 860 may be means for interacting with the input/output device 870. For example, the input device may include a camera including an audio sensor and/or an image sensor, a keyboard, a microphone, and a mouse, and the output device may include a display, a speaker, and a haptic feedback device. In another example, the high-speed interface 850 and the low-speed interface 860 may be means for interfacing with a device in which a configuration or a function for performing input and output operations is integrated, such as a touch screen.

According to an embodiment, the high-speed interface 850 may manage bandwidth-intensive operations for the computing device 800, while the low-speed interface 860 may manage operations that are less bandwidth-intensive than those of the high-speed interface 850. However, such functional assignment is merely exemplary. According to an embodiment, the high-speed interface 850 may be coupled to high-speed expansion ports capable of accommodating the memory 820, the input/output device 870, and various expansion cards (not shown). In addition, the low-speed interface 860 may be coupled to the storage device 830 and a low-speed expansion port. Additionally, the low-speed expansion port, which may include various communication ports (for example, USB, Bluetooth, Ethernet, and wireless Ethernet), may be coupled to one or more input/output devices 870, such as a keyboard, a pointing device, and a scanner, or may be coupled to networking devices such as a router or a switch through a network adapter.

The computing device 800 may be implemented in various different forms. For example, the computing device 800 may be implemented as a standard server or as a group of standard servers. Additionally or alternatively, the computing device 800 may be implemented as a part of a rack server system or as a personal computer such as a laptop computer. In such a case, components of the computing device 800 may be combined with other components within an arbitrary mobile device (not shown). The computing device 800 may include one or more other computing devices, or may be configured to communicate with one or more other computing devices.

FIG. 8 illustrates that the input/output device 870 is not included in the computing device 800, but the present disclosure is not limited thereto, and the input/output device 870 may be integrated with the computing device 800 as a single device. In addition, although FIG. 8 shows the high-speed interface 850 and/or the low-speed interface 860 as being separate from the processor 810, the present disclosure is not limited thereto, and the high-speed interface 850 and/or the low-speed interface 860 may be configured to be included in the processor 810.

The above-described method and/or various embodiments may be implemented in digital electronic circuits, computer hardware, firmware, software, or a combination thereof. Various embodiments of the present disclosure may be executed by a data processing device, such as one or more programmable processors and/or one or more computing devices, or may be implemented as a computer-readable medium and/or a computer program stored on a computer-readable medium. The computer program may be written in any form of programming language, including a compiled language or an interpreted language, and may be distributed in any form, such as a stand-alone program, a module, or a subroutine. The computer program may be distributed across a plurality of computing devices connected through the same network and/or a plurality of distributed computing devices connected via different networks.

The method and/or various embodiments described above may be performed by one or more processors configured to execute one or more computer programs that process, store, and/or manage arbitrary functions by operating based on input data or generating output data. For example, the method and/or various embodiments of the present disclosure may be performed by a special-purpose logic circuit such as a Field Programmable Gate Array (FPGA) or an Application Specific Integrated Circuit (ASIC); an apparatus and/or a system for performing the method and/or various embodiments of the present disclosure may be implemented as a special-purpose logic circuit such as an FPGA or an ASIC.

The one or more processors executing the computer program may include a general-purpose or special-purpose microprocessor and/or one or more processors of an arbitrary type of digital computing device. The processor may receive instructions and/or data from each of the read-only memory and the random-access memory or may receive instructions and/or data from the read-only memory and the random-access memory. In an embodiment of the present disclosure, the components of a computing device performing the method and/or embodiments may include one or more processors for executing instructions; and one or more memories for storing instructions and/or data.

According to an embodiment, the computing device may send and receive data to and from one or more mass storage devices for storing data. For example, the computing device may receive data from a magnetic or optical disc and transmit data to the magnetic or optical disc. A computer-readable medium suitable for storing instructions and/or data related to a computer program may include any form of non-volatile memory including a semiconductor memory device such as an Erasable Programmable Read-Only Memory (EPROM), an Electrically Erasable PROM (EEPROM), and a flash memory device, without being limited thereto. For example, a computer-readable medium may include a magnetic disc such as an internal hard disc or a removable disc, a photomagnetic disk, a CD-ROM disc, and a DVD-ROM disc.

To provide interaction with a user, the computing device may include a display device (for example, a cathode ray tube (CRT) or a liquid crystal display (LCD)) for providing or displaying information to a user and a pointing device (for example, a keyboard, a mouse, or a trackball) through which the user may provide input and/or commands to the computing device by the user, without being limited thereto. In other words, the computing device may further include any other kind of device for providing interaction with the user. For example, the computing device may provide any form of sensory feedback to the user for interaction with the user, including visual feedback, auditory feedback, and/or tactile feedback. In response to the feedback, the user may provide input to the computing device through various gestures including a visual expression, voice, and motion.

In the present disclosure, various embodiments may be implemented in a computing device that includes a back-end component (for example, a data server), a middleware component (for example, an application server), and/or a front-end component. In this connection, the components may be interconnected by any form or any medium of digital data communication, such as a communication network. According to an embodiment, the communication network includes a wired network such as Ethernet, a wired home network (Power Line Communication), a telephone line communication device, and RS-serial communication; a wireless network such as a mobile communication network, a wireless LAN (WLAN), Wi-Fi, and Bluetooth; or a combination of the wired and wireless networks. For example, the communication network may include a local area network (LAN) and a wide area network (WAN).

A computing device based on the illustrative embodiments described herein may be implemented using hardware and/or software configured to interact with a user, including a user device, a user interface (UI) device, a user terminal, or a client device. For example, the computing device may include a portable computing device such as a laptop computer. Additionally or alternatively, the computing device may include a Personal Digital Assistants (PDA), a tablet PC, a game console, a wearable device, an Internet of Things (IoT) device, a virtual reality (VR) device, and an augmented reality (AR) device, but is not limited thereto. The computing device may further include other types of devices configured to interact with a user. In addition, the computing device may include a portable communication device (e.g., a mobile phone, a smartphone, or a wireless cellular phone) suitable for wireless communication over a network, such as a mobile communication network. The computing device may be configured to communicate wirelessly with a network server using wireless communication technologies and/or protocols such as Radio Frequency (RF), Microwave Frequency (MWF), and/or Infrared Ray Frequency (IRF).

Various embodiments of the present disclosure, including specific structural and functional details, are illustrative in nature. Accordingly, the embodiments of the present disclosure are not limited to those described above and may be implemented in various other forms. In addition, the terms used in the present disclosure are intended for describing some embodiments and should not be construed as limiting the embodiments. For example, singular words and the descriptions above may be construed to include plural forms unless the context dictates otherwise.

Unless defined otherwise, terms used in the present disclosure, including technical or scientific terms, may convey the same meaning understood generally by those skilled in the art to which the present disclosure belongs. Among the terms used in the present disclosure, commonly used terms, such as those defined in ordinary dictionaries, should be interpreted to convey the same meaning in the context of related technology.

The present disclosure has been described with reference to particular embodiments; however, various modifications and changes may be made without departing from the technical scope of the present disclosure that may be understood by those skilled in the art to which the present disclosure belongs. In addition, it should be understood that the modifications and changes fall within the technical scope of the appended claims.

[Detailed Description of Main Elements]

| | |
|---|---|
| 510: screen window processor | 511: command window processor |
| 512: content window processor | 513: design window processor |
| 514: setting window processor | 520: clock management unit |
| | processor |
| 521: clock instance generator | 522: scan controller instance |
| | generator |
| 523: test mode controller instance | |
| generator | |
| 530: data storage | 531: clock component storage |
| 532: content storage | 533: clock management unit storage |
| 534: hardware code logic storage | 540: hardware code processor |
| 541: clock hardware code | |
| generator | |
| 542: scan controller hardware | |
| code generator | |
| 543: test mode controller | |
| hardware code generator | |

What is claimed is:

1. A system for designing a clock management unit using a no-code approach, the system comprising:
a memory configured to store at least one instruction;
a clock component storage storing clock component information that configures the clock management unit;
a hardware code logic storage storing hardware code logic for generating the designed clock management unit as hardware code; and
at least one processor configured to execute the at least one instruction stored in the memory,
wherein the at least one instruction comprises instructions for:
generating a clock instance comprising a clock source block, a clock control signal block, and a test multiplexer block based on the clock component information;
generating a test mode controller instance comprising a test mode TDR block and a test control TDR block corresponding to the test multiplexer block;
setting a connection between the test multiplexer block and the test mode controller instance; and
generating the hardware code based on connection information and the hardware code logic of the clock instance and the test mode controller instance.

2. The system for designing a clock management unit of claim 1, wherein the at least one instruction comprises instructions for:
generating a scan controller instance corresponding to the clock control signal block;
setting a connection between the clock control signal block and the scan controller instance; and
generating hardware code based on the scan controller instance, the connection information and the hardware code logic.

3. The system for designing a clock management unit of claim 1, wherein the test mode controller instance is implemented based on a built-in IEEE1687 standard.

4. The system for designing a clock management unit of claim 1, wherein:
the test mode TDR block is configured to activate or deactivate a test mode; and
the test control TDR block is configured to generate a test clock control signal in the test mode.

5. The system for designing a clock management unit of claim 4, wherein the test control TDR block is composed of as many flip-flop blocks as the number of control bits in the clock source block.

6. The system for designing a clock management unit of claim 1, wherein the test mode TDR block and the test control TDR block are each set via an internal joint test action group (IJTAG) interface.

7. The system for designing a clock management unit of claim 1, wherein the clock component is any one of a PLL controller component, a clock divider component, a clock multiplexer component, and a clock gate component.

8. A method for designing a clock management unit using a no-code approach, the method being performed by at least one processor in a computer system comprising a clock component storage storing clock component information that configures the clock management unit and a hardware code logic storage storing hardware code logic for generating the designed clock management unit as hardware code, the method comprising:
generating a clock instance comprising a clock source block, a clock control signal block, and a test multiplexer block based on the clock component information;
generating a test mode controller instance comprising a test mode TDR block and a test control TDR block corresponding to the test multiplexer block;
setting a connection between the test multiplexer block and the test mode controller instance; and
generating the hardware code based on connection information and the hardware code logic of the clock instance and the test mode controller instance.

9. The method for designing a clock management unit of claim 8, further comprising:
generating a scan controller instance corresponding to the clock control signal block:
setting a connection between the clock control signal block and the scan controller instance; and
generating hardware code based on the scan controller instance, the connection information and the hardware code logic.

10. The method for designing a clock management unit of claim 8, wherein the test mode controller instance is implemented based on a built-in IEEE1687 standard.

11. The method for designing a clock management unit of claim 8, wherein:
the test mode TDR block is configured to activate or deactivate a test mode; and
the test control TDR block is configured to generate a test clock control signal in the test mode.

12. The method for designing a clock management unit of claim 11, wherein the test control TDR block is composed of as many flip-flop blocks as the number of control bits in the clock source block.

13. The method for designing a clock management unit of claim 8, wherein the test mode TDR block and the test control TDR block are each set via an internal joint test action group (IJTAG) interface.

14. The method for designing a clock management unit of claim 8, wherein the clock component is any one of a PLL controller component, a clock divider component, a clock multiplexer component, and a clock gate component.
